(19) United States
(12) Patent Application Publication
(10) Pub. No.: US 2026/0231635 A1
(43) Pub. Date: Aug. 6, 2026

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Binyan WANG, Beijing (CN); Yonglin GUO, Beijing (CN); Dan CAO, Beijing (CN); Miao WANG, Beijing (CN); Cong LIU, Beijing (CN); Wenhui GAO, Beijing (CN); Yangpeng WANG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/993,600

(22) PCT Filed: May 16, 2024
(86) PCT No.: PCT/CN2024/093661

§ 371 Date: Jan. 13, 2025

(30) Foreign Application Priority Data
Jun. 1, 2023 (CN) 202310644041.3

(51) Int. Cl. H10K 59/131; G02F 1/1362; H10K 59/80

(52) U.S. Cl. CPC H10K 59/131; G02F 1/13629; H10K 59/80522

(57) ABSTRACT

Provided is a display panel. The display panel includes: a base substrate, having a display region and a peripheral region surrounding the display region; a plurality of pixel units, disposed in the display region; an auxiliary connection structure, wherein the auxiliary connection structure and anode layers of the plurality of pixel units are disposed in a same layer in the peripheral region; a cathode layer, disposed on a side, away from the base substrate, of the auxiliary connection structure, wherein the cathode layer is connected to the auxiliary connection structure; and at least one power trace, configured to receive a first power signal, wherein the at least one power trace is connected to the auxiliary connection structure.

### CROSS-REFERENCE TO RELATED APPLICATIONS

This application is a U.S. national stage of international application No. PCT/CN2024/093661, filed on May 16, 2024, which claims priority to Chinese Patent Application No. 202310644041.3, filed on Jun. 1, 2023 and entitled “DISPLAY PANEL AND DISPLAY DEVICE,” the disclosure of each are herein incorporated by reference in its entirety.

### TECHNICAL FIELD

The present disclosure relates to the technical field of display, and in particular, relates to a display panel and a display device.

### BACKGROUND

A display substrate generally includes a plurality of pixel units arranged in an array in a display region of the display substrate, and power traces (generally referred to as VSS trances) configured to provide a negative power signal to each of the plurality of pixel units.

### SUMMARY

A display panel and a display device are provided. The technical solutions are as follows.

In some embodiments of the present disclosure, a display panel is provided. The display panel includes:
a base substrate, having a display region and a peripheral region surrounding the display region;
a plurality of pixel units, disposed in the display region;
an auxiliary connection structure, wherein the auxiliary connection structure and anode layers of the plurality of pixel units are disposed in a same layer in the peripheral region;
a cathode layer, disposed on a side, away from the base substrate, of the auxiliary connection structure, wherein the cathode layer is connected to the auxiliary connection structure; and
at least one power trace, configured to receive a first power signal, wherein the at least one power trace is connected to the auxiliary connection structure;
wherein the at least one power trace at least includes a first trace layer, wherein a first insulation layer is disposed between the first trace layer and the auxiliary connection structure, the first insulation layer having a first connection region, wherein the first trace layer and the auxiliary connection structure are connected to each other in the first connection region, and a ratio of an area of an orthographic projection of the first connection region on the base substrate to an area of an overlapping region between an orthographic projection of the at least one power trace on the base substrate and an orthographic projection of the auxiliary connection structure on the base substrate is greater than a ratio threshold.

In some embodiments, at least a plurality of slots arranged in a first direction and extending in a second direction are defined in the first connection region, wherein the second direction is intersected with the first direction, and
the first trace layer is connected to the auxiliary connection structure via the plurality of slots.

In some embodiments, a plurality of communication slots between any two adjacent slots of the plurality of slots are further defined in the first connection region, and arranged in the second direction and extend in the first direction.

In some embodiments, a plurality of first vent holes are defined in the auxiliary connection structure, and the plurality of slots and the plurality of communication slots between any two adjacent slots of the plurality of slots form a plurality of block patterns,
wherein an orthographic projection of each of the plurality of block patterns on the base substrate covers an orthographic projection of one of the plurality of first vent holes on the base substrate.

In some embodiments, a shape of the orthographic projection of each of the plurality of block patterns on the base substrate is the same as a shape of the orthographic projection of the one of the plurality of first vent holes on the base substrate, and a center of the orthographic projection of each of the plurality of block patterns on the base substrate is coincided with a center of the orthographic projection of the one of the plurality of first vent holes on the base substrate.

In some embodiments, the shape of the orthographic projection of each of the plurality of block patterns on the base substrate and the shape of the orthographic projection of the one of the plurality of first vent holes on the base substrate are both rectangles, and
a distance between any boundary of one of the plurality of block patterns and a boundary, at a minimum distance from the one of the plurality of block patterns, in four boundaries of the one of the plurality of first vent holes ranges from 5 microns to 9 microns.

In some embodiments, a plurality of second vent holes are defined in the first trace layer, wherein a center of an orthographic projection of each of the plurality of second vent holes on the base substrate is coincided with a center of the orthographic projection of each of the plurality of block patterns on the base substrate,
an area of the orthographic projection of each of the plurality of second vent holes on the base substrate is less than an area of the orthographic projection of each of the plurality of block patterns on the base substrate and is greater than or equal to an area of the orthographic projection of the one of the plurality of first vent holes on the base substrate.

In some embodiments, the at least one power trace includes a second trace layer, a third trace layer, and the first trace layer that are stacked in a direction away from the base substrate; and the display panel further includes a second insulation layer between the second trace layer and the third trace layer, and a third insulation layer between the third trace layer and the first trace layer;
wherein the second insulation layer has a second connection region, and the third insulation layer has a third connection region, wherein the first trace layer and the second trace layer are connected to each other in the second connection region, and the second trace layer and the third trace layer are connected to each other in the third trace layer.

In some embodiments, the first trace layer has a first side face close to the plurality of pixel units, the second trace layer has a second side face close to the plurality of pixel units, and the third trace layer has a third side face close to the plurality of pixel units, wherein
the third side face and the first side face are closer to the plurality of pixel units than the second side face.

In some embodiments, an opening is defined in the second connection region, wherein the opening is designed to expose all regions in the second trace layer;
a plurality of first vias are defined in the third connection region, wherein each of the plurality of first vias is designed to expose part of the third trace layer; and
a plurality of second vias are defined in the first connection region, wherein each of the plurality of second vias is designed to expose part of the first trace layer;
wherein orthographic projections of the plurality of first vias on the base substrate are not overlapped with orthographic projections of the plurality of second vias on the base substrate.

In some embodiments, the plurality of first vias form a plurality of first projections, and the plurality of second vias form a plurality of second projections, wherein the plurality of first projections and the plurality of second projections form a plurality of projection columns arranged in a first direction and extending in a second direction, each of the plurality of projection columns including multiple first projections, multiple second projections, or a combination thereof; and
each of the plurality of first projections is an orthographic projection of one of the plurality of first vias on the base substrate, and each of the plurality of second projections is an orthographic projection of one of the plurality of second vias on the base substrate.

In some embodiments, each of the plurality of projection columns includes the multiple first projections and the multiple second projections that are staggered; wherein
one projection in any two adjacent projections arranged in the first direction is a first projection in a first projection column in any two adjacent projection columns, and another projection in the any two adjacent projections arranged in the first direction is a second projection in a second projection column in the any two adjacent projection columns.

In some embodiments, each of the plurality of projection columns includes the multiple first projections and the multiple second projections that are staggered, wherein the multiple first projections and the multiple second projections in each of the plurality of projection columns are in one-to-one correspondence with each other, and the multiple first projections and corresponding second projections form a plurality of projection groups,
wherein a distance between adjacent projection groups in the second direction is greater than a distance between the first projection and the second projection in each of the plurality of projection groups in the second direction.

In some embodiments, one of two adjacent projection columns includes the multiple first projections, and another of the two adjacent projection columns includes the multiple second projections; and
each of the plurality of projection columns includes a plurality of projection groups, wherein each of the plurality of projection groups includes two projections adjacent in the second direction in the each of the plurality of projection columns, and a distance between adjacent projection groups in the second direction is greater than a distance between the two projections in each of the plurality of projection groups in the second direction.

In some embodiments, the two adjacent projection columns are staggered in the second direction.

In some embodiments, the plurality of projection columns form a plurality of projection column groups, wherein each of the plurality of projection column groups includes a third projection column and a fourth projection column that are adjacent;
wherein the third projection column includes the multiple first projections arranged in the second direction, and the fourth projection column includes the multiple second projections arranged in the second direction and corresponding to the multiple first projections in the third projection column, wherein each of the multiple second projections and a corresponding first projection are arranged in the first direction, and a distance between any adjacent projection column groups in the first direction is greater than a distance between the third projection column and the fourth projection column in each of the plurality of projection column groups in the first direction.

In some embodiments, the plurality of projection columns form a plurality of projection column groups, wherein each of the plurality of projection column groups includes a fifth projection column and a sixth projection column that are adjacent;
wherein the fifth projection column and the sixth projection column in one of any two adjacent projection column groups each include the multiple first projections arranged in the second direction, and the fifth projection column and the sixth projection column in another of the any two adjacent projection column groups each include the multiple second projections arranged in the second direction, wherein a distance between adjacent projection column groups in the first direction is greater than a distance between the fifth projection column and the sixth projection column in each of the plurality of projection column groups in the first direction.

In some embodiments, two adjacent projection column groups are staggered in the second direction.

In some embodiments, the display panel further includes: a first source and drain layer, a first planarization layer, a second source and drain layer, a second planarization layer, a third source and drain layer, a third planarization layer, and an anode layer that are stacked in a direction away from the base substrate in sequence; wherein
the first trace layer in the at least one power trace is disposed in the third source and drain layer, a second trace layer in the at least one power trace is disposed in the first source and drain layer, and a third trace layer in the at least one power trace is disposed in the second source and drain layer; and the first insulation layer is the third planarization layer, a second insulation layer is the first planarization layer, and a third insulation layer is the second planarization layer.

In some embodiments of the present disclosure, a display device is provided. The display device includes: a power supply assembly, and the display panel according to above embodiments;
wherein the power supply assembly is configured to supply power to the display panel.

### BRIEF DESCRIPTION OF DRAWINGS

For clearer description of the technical solutions according to the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of a display panel according to some embodiments of the present disclosure;

FIG. 2 is a local section of a display panel according to some embodiments of the present disclosure;

FIG. 3 is a top view of a base substrate according to some embodiments of the present disclosure;

FIG. 4 is a locally top view of a first insulation layer according to some embodiments of the present disclosure;

FIG. 5 is a locally top view of a film layer where an auxiliary connection structure is located according to some embodiments of the present disclosure;

FIG. 6 is a locally top view of a film layer where a first trace layer is located according to some embodiments of the present disclosure;

FIG. 7 is a locally schematic diagram of stack of a film layer where a first trace layer is located, a first insulation layer, and a film layer where an auxiliary connection structure is located according to some embodiments of the present disclosure;

FIG. 8 is a local section of a display panel according to some embodiments of the present disclosure;

FIG. 9 is a locally top view of a film layer where a second trace layer is located according to some embodiments of the present disclosure;

FIG. 10 is a locally top view of a second insulation layer according to some embodiments of the present disclosure;

FIG. 11 is a locally top view of a film layer where a second trace layer is located, and a second insulation layer according to some embodiments of the present disclosure;

FIG. 12 is a locally top view of a film layer where a third trace layer is located according to some embodiments of the present disclosure;

FIG. 13 is a locally top view of a third insulation layer according to some embodiments of the present disclosure;

FIG. 14 is a locally top view of a film layer where a third trace layer is located, and a third insulation layer according to some embodiments of the present disclosure;

FIG. 15 is a locally top view of a film layer where a second trace layer is located, a second insulation layer, and a film layer where a third trace layer is located according to some embodiments of the present disclosure;

FIG. 16 is a locally top view of a film layer where a second trace layer is located, a second insulation layer, a film layer where a third trace layer is located, and a third insulation layer according to some embodiments of the present disclosure;

FIG. 17 is a locally top view of a film layer where a first trace layer is located according to some embodiments of the present disclosure;

FIG. 18 is a locally top view of a first insulation layer according to some embodiments of the present disclosure;

FIG. 19 is a locally top view of a film layer where a first trace layer is located, and a first insulation layer according to some embodiments of the present disclosure;

FIG. 20 is a locally top view of a third insulation layer and a first insulation layer according to some embodiments of the present disclosure;

FIG. 21 is a locally schematic diagram of FIG. 20;

FIG. 22 is a locally top view of a third insulation layer and a first insulation layer according to some embodiments of the present disclosure;

FIG. 23 is a locally schematic diagram of FIG. 22;

FIG. 24 is a locally top view of a third insulation layer and a first insulation layer according to some embodiments of the present disclosure;

FIG. 25 is a locally schematic diagram of FIG. 24;

FIG. 26 is a locally top view of a third insulation layer and a first insulation layer according to some embodiments of the present disclosure;

FIG. 27 is a locally schematic diagram of FIG. 26;

FIG. 28 is a locally top view of a third insulation layer and a first insulation layer according to some embodiments of the present disclosure;

FIG. 29 is a locally schematic diagram of FIG. 28;

FIG. 30 is a locally top view of a first source and drain layer according to some embodiments of the present disclosure;

FIG. 31 is a locally top view of a first planarization layer according to some embodiments of the present disclosure;

FIG. 32 is a locally top view of a second source and drain layer according to some embodiments of the present disclosure;

FIG. 33 is a locally top view of a second planarization layer according to some embodiments of the present disclosure;

FIG. 34 is a locally top view of a second source and drain layer and a third source and drain layer according to some embodiments of the present disclosure;

FIG. 35 is a section at an AA direction in FIG. 34; and

FIG. 36 is a schematic structural diagram of a display device according to some embodiments of the present disclosure.

### DETAILED DESCRIPTION

For clearer descriptions of the objects, technical solutions, and advantages of the present disclosure, the embodiments of the present disclosure are described in detail hereinafter in combination with the accompanying drawings.

In some practices, a display substrate includes a peripheral region surrounding a display region. A VSS trace is configured to connect drive circuits, and is connected to a cathode layer of a pixel unit in the display region of the base substrate to provide a negative power signal from the drive circuit to the cathode layer of the pixel unit. For transmission of a VSS signal from the VSS trace to the cathode layer of the pixel unit, the VSS signal is generally transmitted to a connection pattern using a signal layer of metal, and is then transmitted to the cathode layer over the connection pattern.

However, the reliability of a solution of transmitting the VSS signal using the signal layer of metal, the pixel unit further fails to emit light, and the display effect of the display panel is poor.

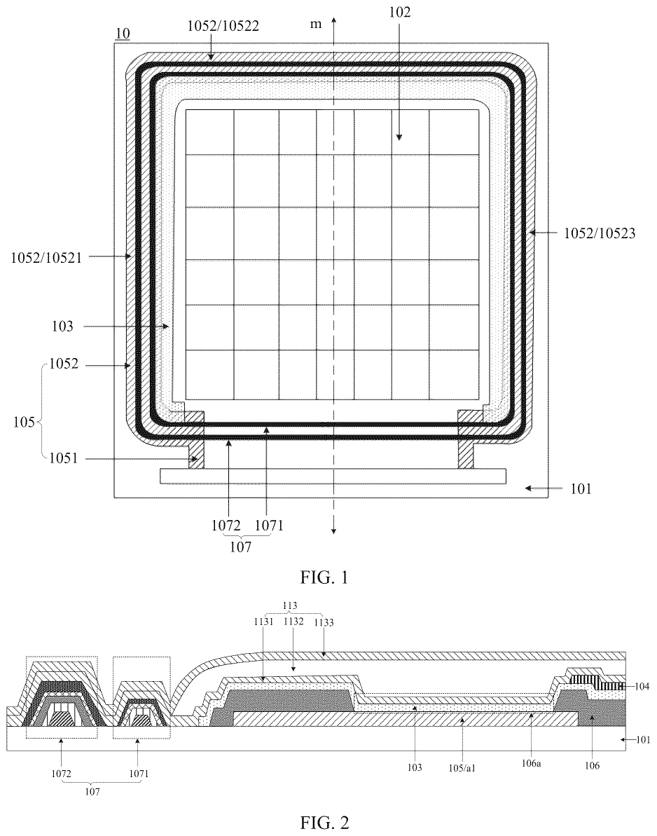

FIG. 1 is a schematic structural diagram of a display panel according to some embodiments of the present disclosure. FIG. 2 is a local section of a display panel according to some embodiments of the present disclosure. It can be seen referring to FIG. 1 and FIG. 2 that the display panel 10 includes a base substrate 101, a plurality of pixel units 102, an auxiliary connection structure 103, a cathode layer 104, at least one power trace 105, and a first insulation layer 106.

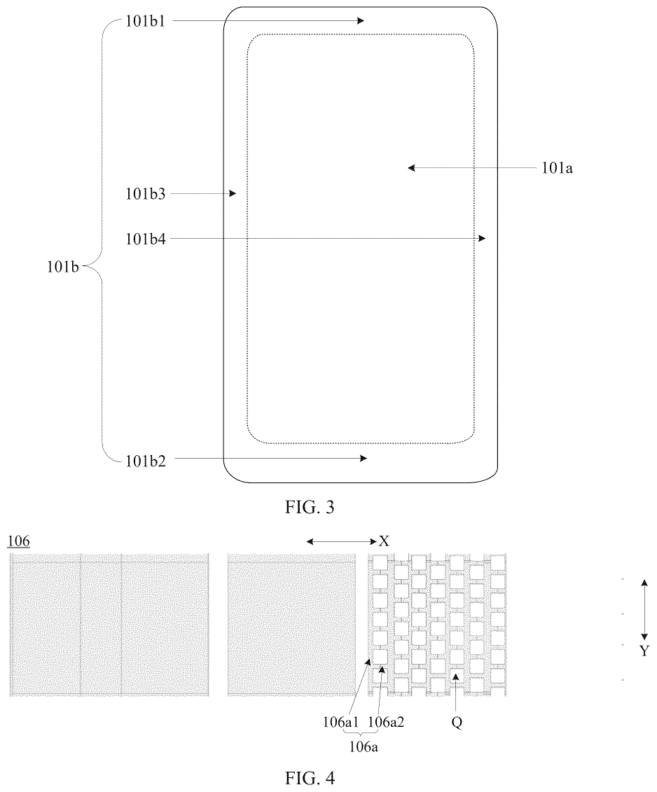

FIG. 3 is a top view of a base substrate according to some embodiments of the present disclosure. It can be seen referring to FIG. 3 that the base substrate 101 has a display region 101a and a peripheral region 101b surrounding the display region 101a.

In conjunction with FIG. 1 to FIG. 3, the plurality of pixel units 102 are disposed in the display region 101a. A blocking structure 107 is disposed in the peripheral region 101b and surrounds the display region 101a. The auxiliary connection structure 103 and anode layers of the plurality of pixel units 102 are disposed in a same layer in the peripheral region 101b. The auxiliary connection structure 103 shown in FIG. 1 is disposed on an upper side, a left side, and a right side, and may also be disposed on a lower side, which is not limited in the embodiments of the present disclosure.

The cathode layer 104 is disposed on a side, away from the base substrate 101, of the auxiliary connection structure 103. The cathode layer 104 is connected to the auxiliary connection structure 104. The at least one power trace 105 is configured to receive a power signal and is connected to the auxiliary connection structure 103.

Referring to FIG. 2, the at least one power trace 105 at least includes a first trace layer a1. The first insulation layer 106 is disposed between the first trace layer a1 and the auxiliary connection structure 103 and has a first connection region 106a, the first trace layer a1 and the auxiliary connection structure 103 are connected to each other in the first connection region 106a, and a ratio of an area of an orthographic projection of the first connection region 106a on the base substrate 101 to an area of an overlapping region between an orthographic projection of the at least one power trace 105 on the base substrate 101 and an orthographic projection of the auxiliary connection structure 103 on the base substrate 101 is greater than a ratio threshold. In some embodiments, the ratio threshold is 1.3%.

In the case that the at least one power trace 105 is connected to the auxiliary connection structure 103, the connection position is in an overlapping region between the at least one power trace 105 and the auxiliary connection structure 103. Thus, for connection of the at least one power trace 105 and the auxiliary connection structure 103, the orthographic projection of the first connection region 106a in the first insulation layer 106 on the base substrate 101 needs to be within the overlapping region. As the ratio of the area of the orthographic projection of the first connection region 106a on the base substrate 101 to the area of the overlapping region is great, a contacting area of the first trace layer a1 in the power trace 105 and the auxiliary connection structure 103 is great. Furthermore, the reliability of the connection between the first trace layer a1 in the power trace 105 and the auxiliary connection structure 103 is improved, and the reliability of transmission of the power signal from the power trace 105 to the auxiliary connection structure 103 is further improved, such that the pixel unit emits light normally, and the display effect of the display panel 10 is great.

In summary, the embodiments of the present disclosure provide a display panel. The display panel includes the power trace and the auxiliary connection structure, and the first connection region is disposed in the first insulation layer between the first trace layer in the power trace and the auxiliary connection structure. As the ratio of the area of the orthographic projection of the first connection region on the base substrate to the area of the overlapping region between the orthographic projection of the power trace on the base substrate and the orthographic projection of the auxiliary connection structure on the base substrate is great, the contacting area of the first trace layer in the power trace and the auxiliary connection structure is great, the reliability of the connection between the first trace layer in the power trace and the auxiliary connection structure is improved, and the reliability of transmission of the power signal from the power trace to the auxiliary connection structure is further improved, such that the pixel unit emits light normally, and the display effect of the display panel is great.

Referring to FIG. 1, the display panel 10 further includes a blocking structure 107. The orthographic projection of the power trace 105 on the base substrate 101 is partially overlapped with an orthographic projection of the blocking structure 107 on the base substrate 101, such that part of the power trace 105 is disposed on a side, close to the display region 101a, of the blocking structure 107 to be connected to the auxiliary connection structure 103, and another part of the power trace 105 is disposed on a side, away from the display region 101a, of the blocking structure to receive the power signal.

In some embodiments, the orthographic projection of the blocking structure 107 on the base substrate 101 is an annular structure. The part of the power trace 105 on the side, close to the display region 101a, of the blocking structure 107 is within a region enclosed by the blocking structure 107, and the another part of the power trace 105 is disposed on the side, away from the display region 101a, of the blocking structure 107 is disposed outside the region enclosed by the blocking structure 107. Thus, the power trace 105 is capable of running through the blocking structure 107 to enter the region enclosed by the blocking structure 107. Part of the blocking structure 107 for running through by the power trace 105 is also referred to as a trace-entering opening (a port).

In a first alternative implementation, the power trace 105 transmits the power signal to the auxiliary connection structure 103 over a single trace layer (the first trace layer a1).

FIG. 4 is a locally top view of a first insulation layer according to some embodiments of the present disclosure. Referring to FIG. 4, at least a plurality of slots 106a1 arranged in a first direction X and extending in a second direction Y are defined in the first connection region 106a. The first trace layer a1 is connected to the auxiliary connection structure 103 via the plurality of slots 106a1. The plurality of slots 106a1 may be stripe slots 106a1. Compared with the solution of connection of the first trace layer a1 and the auxiliary connection structure 103 over a plurality of vias, the contacting area of the first trace layer a1 and the auxiliary connection structure 103 is great in the solution of connection of the first trace layer a1 and the auxiliary connection structure 103 via the plurality of stripe slots 106a1 in the embodiments of the present disclosure. In FIG. 4, the filled pattern represents a region without a material of the first insulation layer, and a region without the filled pattern represents a region having the material of the first insulation layer.

The first direction X is intersected with the second direction Y. For example, the first direction X is a row direction of pixels in the display panel 10, and the second direction Y is a column direction of pixels in the display panel 10.

Furthermore, referring to FIG. 4, a plurality of communication slots 106a2 between any two adjacent slots of the plurality of slots 106a1 are further defined in the first connection region 106a, and arranged in the second direction Y and extend in the first direction X.

A length of the communication slot 106a2 in the first direction X is equal to a distance between two adjacent slots 106a1 in the first direction X, such that the two adjacent slots 106a1 and the plurality of communication slots 106a2 between the two adjacent slots 106a1 form a connected slot structure.

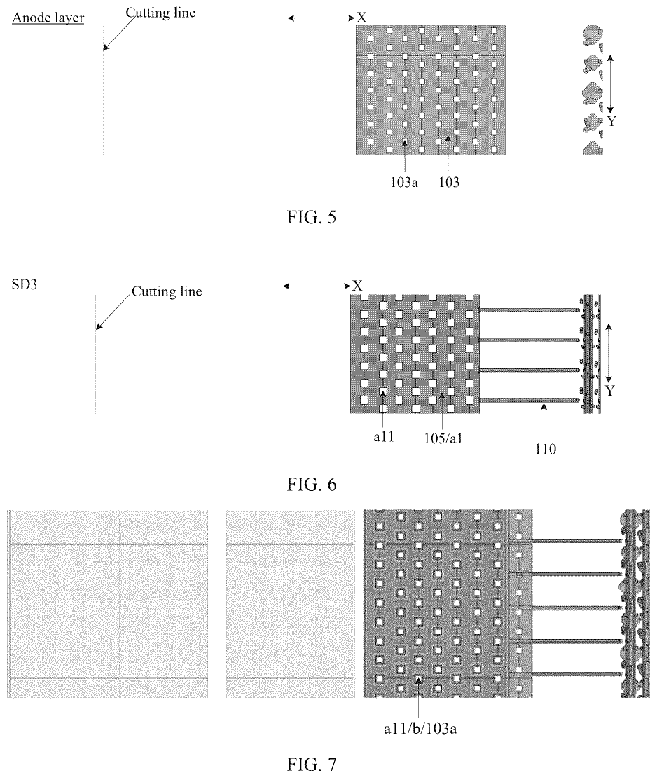

FIG. 5 is a locally top view of a film layer where an auxiliary connection structure is located according to some embodiments of the present disclosure. Referring to FIG. 5, a plurality of first vent holes 103a are defined in the auxiliary connection structure 103. The plurality of first vent holes 103a are designed to exhaust the gas in the film layer.

Referring to FIG. 4, the plurality of slots 106a1 and the plurality of communication slots 106a2 between any two adjacent slots of the plurality of slots 106a1 form a plurality of block patterns Q. The plurality of block patterns Q may be patterns in the region without the communication slot 106a2 structure in the first insulation layer 106. For example, in FIG. 5, a shape of an orthographic projection of each of the plurality of block patterns Q on the base substrate 101 is rectangle.

The orthographic projection of each of the plurality of block patterns Q on the base substrate 101 covers an orthographic projection of one of the plurality of first vent holes 103a on the base substrate 101, such that an effect of the plurality of slots 106a1 or the plurality of communication slots 106a2 in the first insulation layer 106 on the gas exhausting effect of the plurality of first vent holes 103a is avoided.

In some embodiments, a shape of the orthographic projection of each of the plurality of block patterns Q on the base substrate 101 is the same as a shape of the orthographic projection of the one of the plurality of first vent holes 103a on the base substrate 101. For example, in FIG. 4 and FIG. 5, the shape of the orthographic projection of each of the plurality of block patterns Q on the base substrate 101 and the shape of the orthographic projection of the one of the plurality of first vent holes 103a on the base substrate 101 are both rectangles. Alternatively, the shape of the orthographic projection of the one of the plurality of first vent holes 103a on the base substrate 101 is a diamond, a round, a rounded square, and the like. the embodiments of the present disclosure do not limit the shape of the orthographic projection of the one of the plurality of first vent holes 103a on the base substrate 101.

In some embodiments, a width of each of the plurality of block patterns Q in the first direction X and a width of each of the plurality of block patterns Q in the second direction Y each range from 22 microns (μm) to 26 μm, and a width of each of the plurality of first vent holes 103a in the first direction X and a width of each of the plurality of first vent holes 103a in the second direction Y each range from 8 μm to 12 μm. A center of the orthographic projection of each of the plurality of block patterns Q on the base substrate 101 is coincided with a center of the orthographic projection of the one of the plurality of first vent holes 103a on the base substrate 101. A distance between any boundary of one of the plurality of block patterns Q and a boundary, at a minimum distance from the one of the plurality of block patterns Q, in four boundaries of the one of the plurality of first vent holes 103a ranges from 5 μm to 9 μm.

FIG. 6 is a locally top view of a film layer where a first trace layer is located according to some embodiments of the present disclosure. FIG. 7 is a locally schematic diagram of stack of a film layer where a first trace layer is located, a first insulation layer, and a film layer where an auxiliary connection structure is located according to some embodiments of the present disclosure. Referring to FIG. 6 and FIG. 7, a plurality of second vent holes a11 are defined in the first trace layer a1 in the power trace 105. A center of an orthographic projection of each of the plurality of second vent holes a11 on the base substrate 101 is coincided with a center of the orthographic projection of each of the plurality of block patterns Q on the base substrate 101.

In some embodiments, a shape of the orthographic projection of each of the plurality of second vent holes a11 on the base substrate 101 is the same as the shape of the orthographic projection of each of the plurality of block patterns Q on the base substrate 101 and the shape of the orthographic projection of the one of the plurality of first vent holes 103a on the base substrate 101. For example, the shape of the orthographic projection of each of the plurality of second vent holes a11 on the base substrate 101 is a rectangle. Alternatively, the shape of the orthographic projection of each of the plurality of second vent holes a11 on the base substrate 101 is a diamond, a round, a rounded square, and the like. the embodiments of the present disclosure do not limit the shape of the orthographic projection of each of the plurality of second vent holes a11 on the base substrate 101.

In addition, an area of the orthographic projection of each of the plurality of second vent holes a11 on the base substrate 101 is less than an area of the orthographic projection of each of the plurality of block patterns Q on the base substrate 101, such that each of the plurality of block patterns Q covers the second vent hole a11, and an effect of the plurality of slots 106a1 or the plurality of communication slots 106a2 in the first insulation layer 106 on the gas exhausting effect of the plurality of second vent holes a11 is avoided. In addition, the area of the orthographic projection of each of the plurality of second vent holes a11 on the base substrate 101 is greater than or equal to an area of the orthographic projection of the one of the plurality of first vent holes 103a on the base substrate 101. Illustratively, a width of each of the plurality of second vent holes a11 in the first direction X and a width of each of the plurality of second vent holes a11 in the second direction Y each range from 12 μm to 16 μm.

In a second alternative implementation, the power trace 105 transmits the power signal to the auxiliary connection structure 103 over three trace layers.

Referring to FIG. 8, the at least one power trace 105 includes a second trace layer a2, a third trace layer a3, and the first trace layer a1 that are stacked in a direction away from the base substrate 101. The display panel 10 further includes a second insulation layer 108 between the second trace layer a2 and the third trace layer a3, and a third insulation layer 109 between the third trace layer a3 and the first trace layer a1.

The second insulation layer 108 has a second connection region 108a, and the third insulation layer 109 has a third connection region 109a. The first trace layer a1 and the second trace layer a2 are connected to each other in the second connection region 108a, and the second trace layer a2 and the third trace layer a3 is connected to each other in the third connection region 109a.

In the embodiments of the present disclosure, as the power trace 105 transmits the power signal over three trace layers, the reliability of transmission of the power signal by the power trace 105 is improved, and the pixel unit emits light normally.

As some circuit patterns k in the gate driven on array (GOA) circuit in the display panel 10 is generally designed in the film layer where the second trace layer a2 is located (the first source and drain layer SD1), a length of the second trace layer a2 in the first direction X is less and the third trace layer a3 and the circuit pattern k in the film layer where the second trace layer a2 is located in the GOA circuit are partitioned to avoid mutual effect of the second trace layer a2 and the GOA circuit in the layout.

In some embodiments, the second trace layer a2 is farther away from the display region 101a than the circuit pattern k in the GOA circuit.

In general, the overlapping region of the power trace 105 and the auxiliary connection structure 103 is overlapped with an orthographic projection of the circuit pattern k in the GOA circuit on the base substrate 101. Thus, for connection between the power trace 105 and the auxiliary connection structure 103, orthographic projections of the third trace layer a3 and the first trace layer a1 in the power trace 105 on the base substrate 101 are overlapped with the orthographic projection of the circuit pattern k in the GOA circuit on the base substrate 101.

That is, in the embodiments of the present disclosure, referring to FIG. 8, the first trace layer a1 has a first side face a1a close to the plurality of pixel units 102, the second trace layer a2 has a second side face a2a close to the plurality of pixel units 102, and the third trace layer a3 has a third side face a3a close to the plurality of pixel units 102. The third side face a3a and the first side face a1a are closer to the plurality of pixel units 102 than the second side face a2a.

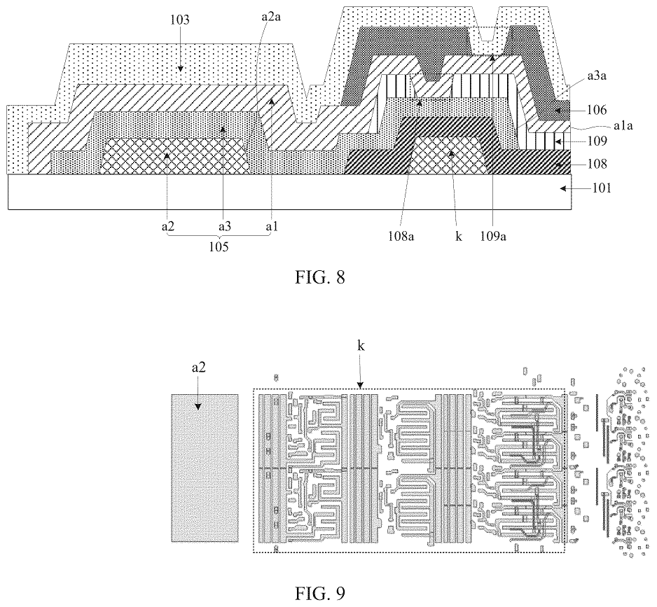

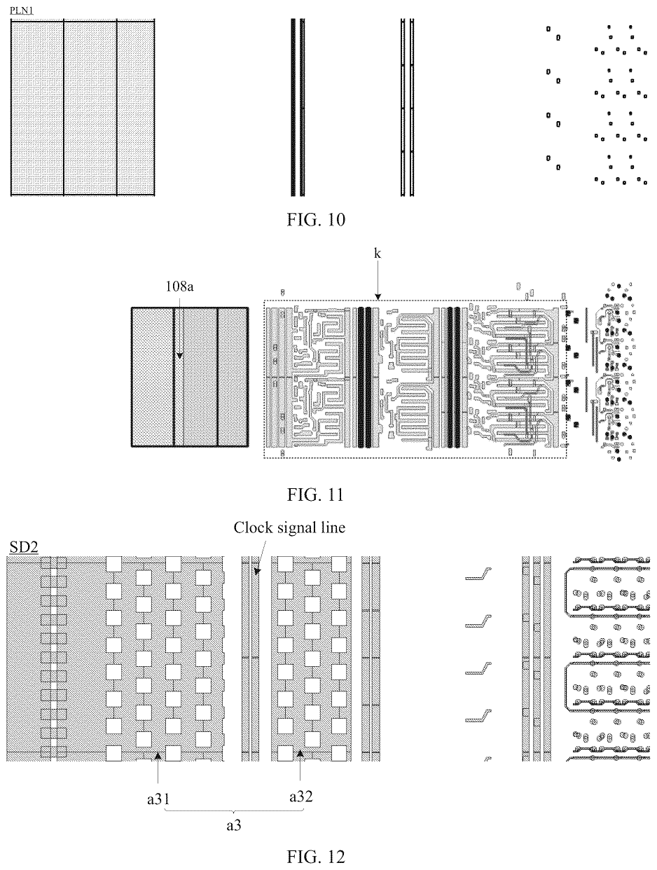

FIG. 9 is a locally top view of a film layer where a second trace layer is located according to some embodiments of the present disclosure. FIG. 10 is a locally top view of a second insulation layer according to some embodiments of the present disclosure. FIG. 11 is a locally top view of a film layer where a second trace layer is located, and a second insulation layer according to some embodiments of the present disclosure. Referring to FIG. 9 to FIG. 11, an opening is defined in the second connection region 108a to expose all regions in the second trace layer a2. That is, in the case that the third trace layer a3 on the second insulation layer 108 is connected to the second trace layer a2 via the opening, all regions in the second trace layer a2 is in contact with the third trace layer a3, and thus a contacting area of the second trace layer a2 and the third trace layer a3 is great. In FIG. 10, the filled pattern represents a region without a material of the second insulation layer, and a region without the filled pattern represents a region having the material of the second insulation layer.

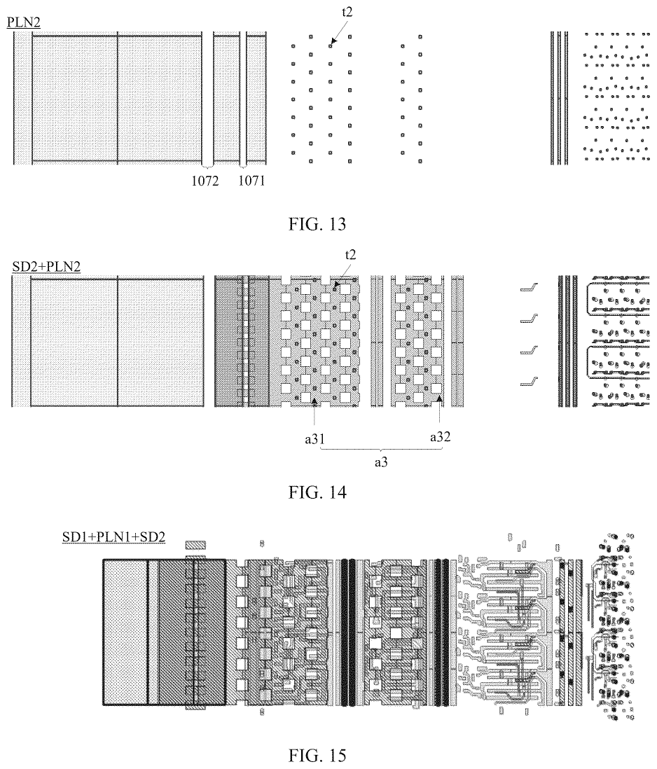

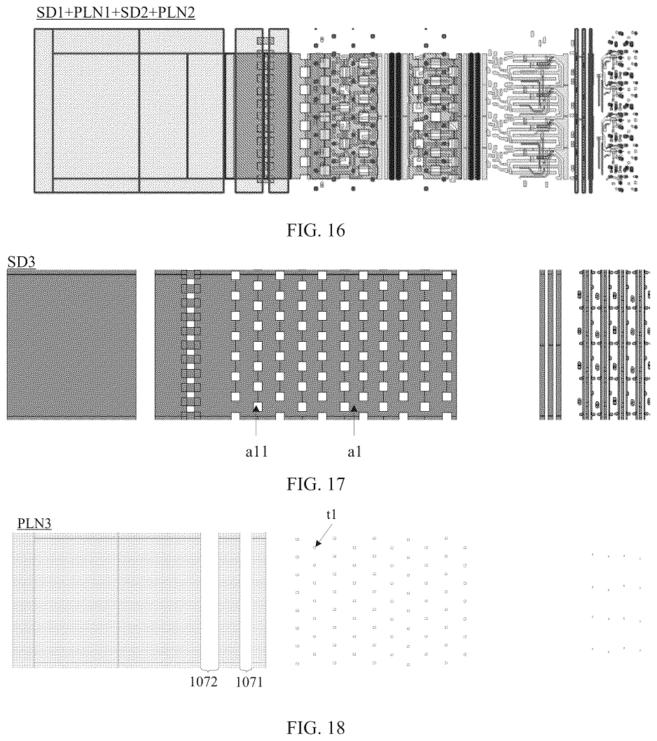

FIG. 12 is a locally top view of a film layer where a third trace layer is located according to some embodiments of the present disclosure. FIG. 13 is a locally top view of a third insulation layer according to some embodiments of the present disclosure. FIG. 14 is a locally top view of a film layer where a third trace layer is located, and a third insulation layer according to some embodiments of the present disclosure. FIG. 15 is a locally top view of a film layer where a second trace layer is located, a second insulation layer, and a film layer where a third trace layer is located according to some embodiments of the present disclosure. FIG. 16 is a locally top view of a film layer where a second trace layer is located, a second insulation layer, a film layer where a third trace layer is located, and a third insulation layer according to some embodiments of the present disclosure. Referring to FIG. 12 to FIG. 16, a plurality of first vias are defined in the third connection region 109a. Each of the plurality of first vias is designed to expose part of the third trace layer a3. That is, the first trace layer a1 on the third insulation layer 109 is connected to the third trace layer a3 via the plurality of first vias. In FIG. 13, the filled pattern represents a region without a material of the third insulation layer, and a region without the filled pattern represents a region having the material of the third insulation layer.

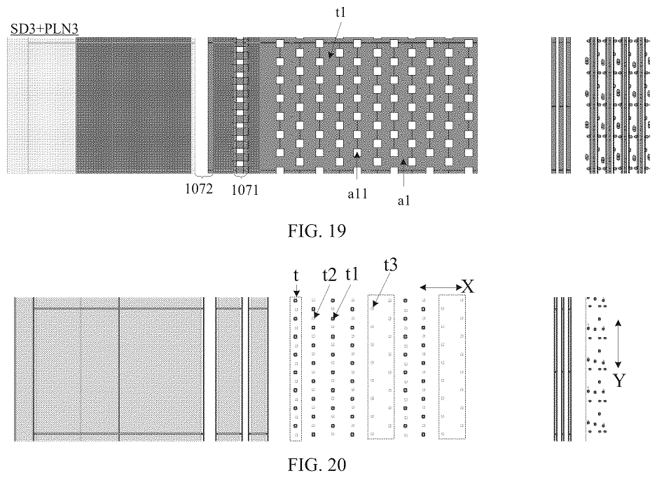

FIG. 17 is a locally top view of a film layer where a first trace layer is located according to some embodiments of the present disclosure. FIG. 18 is a locally top view of a first insulation layer according to some embodiments of the present disclosure. FIG. 19 is a locally top view of a film layer where a first trace layer is located, and a first insulation layer according to some embodiments of the present disclosure. Referring to FIG. 17 to FIG. 19, a plurality of second vias are defined in the first connection region 106a. Each of the plurality of second vias is designed to expose part of the first trace layer a1. That is, the auxiliary connection structure 103 on the first insulation layer 106 is connected to the first trace layer a1 via the plurality of second vias. In FIG. 18, the filled pattern represents a region without a material of the first insulation layer, and a region without the filled pattern represents a region having the material of the first insulation layer.

FIG. 20 is a locally top view of a third insulation layer and a first insulation layer according to some embodiments of the present disclosure. Referring to FIG. 20, orthographic projections of the plurality of first vias on the base substrate 101 are not overlapped with orthographic projections of the plurality of second vias on the base substrate 101 to avoid mutual effect of the plurality of first vias in the third insulation layer 109 and the plurality of second vias in the first insulation layer 106.

In some embodiments, a number of the plurality of first vias is the same as a number of the plurality of second vias, such that uniformity of the plurality of first vias in the third insulation layer 109 and the plurality of second vias in the first insulation layer 106 is great, and the flowing uniformity of the third insulation layer 109 and the first insulation layer 106 is ensured.

In some embodiments, referring to FIG. 20, the plurality of first vias form a plurality of first projections t1, and the plurality of second vias form a plurality of second projections t2. The plurality of first projections t1 and the plurality of second projections t2 form a plurality of projection columns t arranged in the first direction X and extending in the second direction Y. Each of the plurality of projection columns t includes multiple first projections t1 and/or multiple second projections t2. That is, each of the plurality of projection columns t includes multiple first projections t1. Alternatively, each of the plurality of projection columns t includes multiple second projections t2. Alternatively, each of the plurality of projection columns t includes multiple first projections t1 and multiple second projections t2.

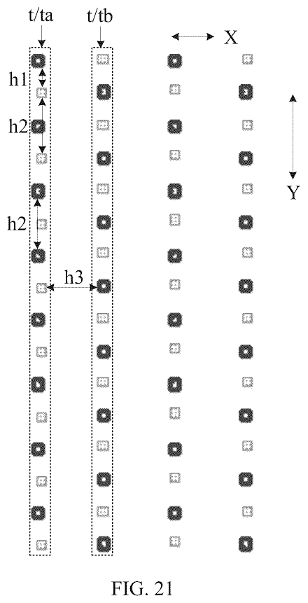

In a first case, referring to FIG. 20 and FIG. 21, each of the plurality of projection columns t includes the multiple first projections t1 and the multiple second projections t2 that are staggered. That is, one projection in two adjacent projections in each of the plurality of projection columns t is the first projection t1, and the other projection in the two adjacent projections in each of the plurality of projection columns t is the second projection t2.

In some embodiments, referring to FIG. 21, a distance h1 between two adjacent projections (the first projection t1 and the second projection t2) in each of the plurality of projection columns t in the second direction Y ranges from 3.2 μm to 15 μm. In addition, a distance h2 between two adjacent projections in the same film layer (two first projections t1 or two second projections t2) in each of the plurality of projection columns t in the second direction Y ranges from 6.4 μm to 30 μm. The distance between two adjacent projections in the same film layer in each of the plurality of projection columns in the second direction Y is equal to a sum of a twice of the distance between two adjacent projections in each of the plurality of projection columns in the second direction Y and a length of each projection in the second direction Y.

In addition, in two adjacent projections arranged in the first direction X, one projection is the first projection t1 in a first projection column ta in two adjacent projection columns t, and the other projection is the second projection t2 in a second projection column tb in the two adjacent projection columns t.

Illustratively, in the first projection column ta and the second projection column tb that are adjacent, the first projection t1 in the first projection column ta and the second projection t2 in the second projection column tb are arranged in the first direction X. Alternatively, in the first projection column ta and the second projection column tb that are adjacent, the second projection t2 in the first projection column ta and the first projection t1 in the second projection column tb are arranged in the first direction X. The arrangement mode is called as staggered arrangement of two adjacent projection columns in the second direction Y.

In addition, a distance h3 between two adjacent projection columns t in the first direction X ranges from 16 μm to 36 μm. The distance between two adjacent projection columns t in the first direction X may refer to a distance between projections of the two adjacent projection columns t in the first direction X.

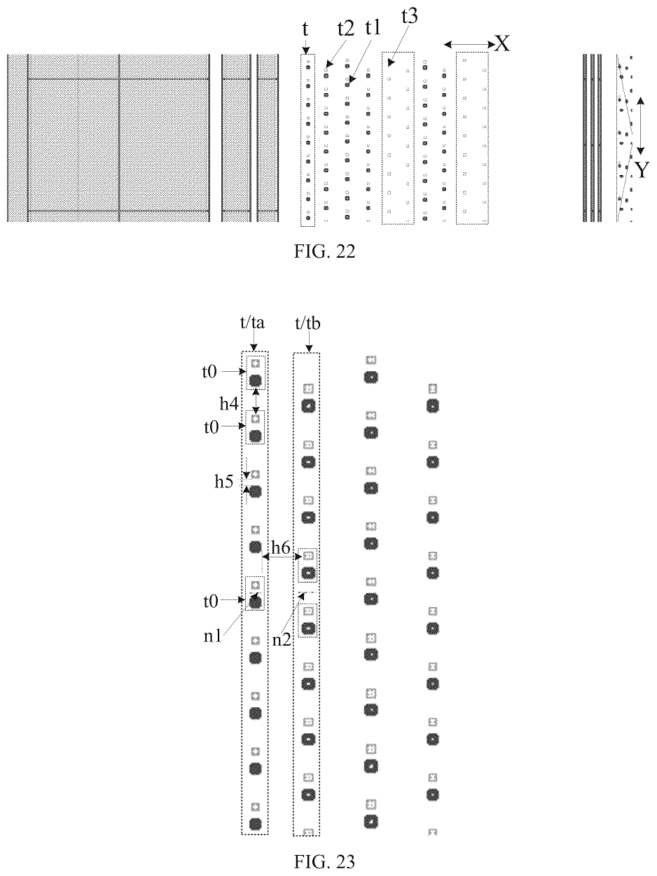

In a second case, referring to FIG. 22 and FIG. 23, each of the plurality of projection columns t includes the multiple first projections t1 and the multiple second projections t2 that are staggered. The multiple first projections t1 and the multiple second projections t2 in each of the plurality of projection columns t are in one-to-one correspondence, and each of the multiple first projections t1 and a corresponding second projection t2 form a projection group t0.

Illustratively, each projection group t0 includes a first projections t1 and a second projection t2 arranged in the second direction Y. In addition, in two closest projections in two adjacent projection groups t0, one projection is the second projection t2, and the other projection is the first projection t1.

In some embodiments, referring to FIG. 23, a distance h4 between adjacent projection groups to in the second direction Y is greater than or equal to a distance h5 between the first projection t1 and the second projection t2 in each projection group t0 in the second direction Y. Illustratively, the distance h4 between adjacent projection groups t0 in the second direction Y ranges from 2 μm to 14 μm, and the distance h5 between the first projection t1 and the second projection t2 in each projection group t0 in the second direction Y ranges from 2 μm to 14 μm.

In addition, two adjacent projection columns t are staggered in the second direction Y. For example, for the first projection column ta and the second projection column tb that are adjacent, a center line n1 of the first projection t1 and the second projection t2 in the projection group t0 in the first projection column ta in the first direction X and a center line n2 of two adjacent projection groups t0 in the second projection column tb in the first direction X are approximately in the same horizontal line.

In some embodiments, a distance h6 between two adjacent projection columns t in the first direction X ranges from 16 μm to 36 μm. The distance between two adjacent projection columns t in the first direction X may refer to a distance between projections of the two adjacent projection columns t in the first direction X.

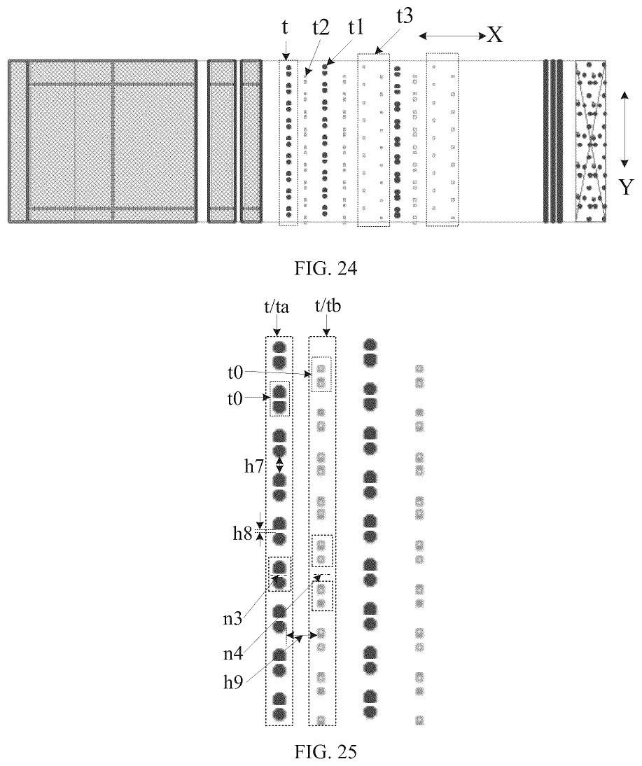

In a third case, referring to FIG. 24 and FIG. 25, one of two adjacent projection columns t includes the multiple first projections t1, and the other of the two adjacent projection columns t includes the multiple second projections t2. That is, multiple projections in each projection column t are all first projections t1 or are all second projections t2.

Each of the plurality of projection columns t includes a plurality of projection groups t0. Each of the plurality of projection groups t0 includes two projections adjacent in the second direction Y in the each of the plurality of projection columns t. Illustratively, multiple projections in the first projection column ta are all first projections t1, and each of the plurality of projection groups t0 in the first projection column ta includes two first projections t1 adjacent in the second direction Y. Multiple projections in the second projection column tb are all second projections t2, and each of the plurality of projection groups t0 in the second projection column tb includes two second projections t2 adjacent in the second direction Y. The first projection column ta and the second projection column tb are two adjacent projection columns t.

In some embodiments, referring to FIG. 25, a distance h7 between adjacent projection groups t0 in the second direction Y is greater than or equal to a distance h8 between the two projections in each of the plurality of projection groups t0 in the second direction Y.

Illustratively, the distance h7 between adjacent projection groups t0 in the second direction Y in each projection group t ranges from 2 μm to 14 μm, and the distance h8 between the two projections in each of the plurality of projection groups t0 in the second direction Y ranges from 2 μm to 14 μm.

In addition, two adjacent projection columns t are staggered in the second direction Y. For example, for the first projection column ta and the second projection column tb that are adjacent, a center line n3 of the two projections in the projection group t0 in the first projection column ta in the first direction X and a center line n4 of two adjacent projection groups t0 in the second projection column tb in the first direction X are approximately in the same horizontal line.

In some embodiments, a distance h9 between two adjacent projection columns t in the first direction X ranges from 16 μm to 36 μm. The distance between two adjacent projection columns t in the first direction X may refer to a distance between projections of the two adjacent projection columns t in the first direction X.

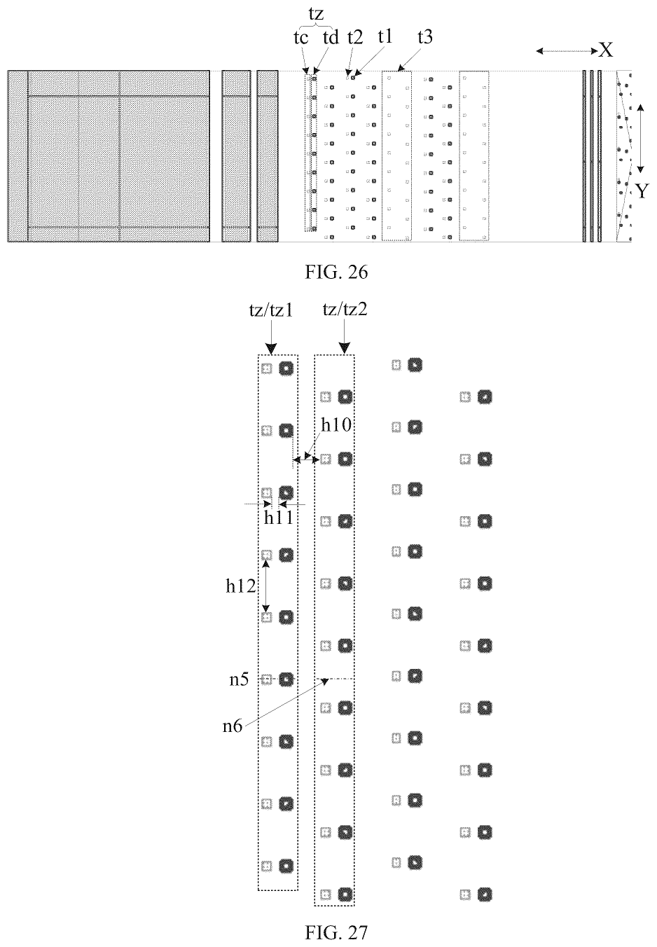

In a fourth case, referring to FIG. 26 and FIG. 27, the plurality of projection columns t form a plurality of projection column groups tz. Each of the plurality of projection column groups tz includes a third projection column te and a fourth projection column td that are adjacent. The third projection column tc includes the multiple first projections t1 arranged in the second direction Y, and the fourth projection column td includes the multiple second projections t2 arranged in the second direction Y and corresponding to the multiple first projections t1 in the third projection column tc. In the projection column group tz, the first projection t1 in the third projection column tz and the corresponding second projection t2 in the fourth projection column td are arranged in the first direction X.

That is, for two adjacent projection columns t in each projection column group tz, multiple projections in one projection column t are all first projections t1, and multiple projections in the other projection column t are all second projections t2.

In some embodiments, referring to FIG. 27, a distance h10 between adjacent projection column groups tz in the first direction X is greater than a distance h11 between the third projection column te and the fourth projection column td in each of the plurality of projection column groups tz in the first direction X. The distance between adjacent projection column groups tz in the first direction X may refer to a distance between two closest projection columns in adjacent projection column groups tz in the first direction X. In two closest projection columns t, one projection column t is the fourth projection column td in a projection column group tz, and the other projection column t is the third projection column te in another projection column group tz.

For example, assuming that the plurality of projection columns t arranged in the first direction X are the third projection column tc and the fourth projection column td in the first projection column group tz1, and the third projection column tc and the fourth projection column td in the second projection column group tz2 in sequence, then a distance between the first projection column group tz1 and the second projection column group tz2 in the first direction X may refer to a distance between the fourth projection column td in the first projection column group tz1 and the third projection column te in the second projection column group tz2 in the first direction X.

Illustratively, the distance h10 between adjacent projection column groups tz in the first direction X ranges from 16 μm to 36 μm, and the distance h11 between the third projection column tc and the fourth projection column td in each of the plurality of projection column groups tz in the first direction X ranges from 2 μm to 6.5 μm.

In some embodiments, the distance between two adjacent projections arranged in the second direction Y in each projection column t in the second direction Y is the same. For example, the distance h12 between two adjacent projections arranged in the second direction Y in each projection column t in the second direction Y ranges from 2 μm to 30 μm.

In addition, two adjacent projection column groups tz are staggered in the second direction Y. For example, for two adjacent projection column groups tz, a center line n5 of projections in one projection column group tz in the first direction X and a center line n6 of two projections arranged in the second direction Y in the other projection column group tz in the first direction X are approximately in the same horizontal line.

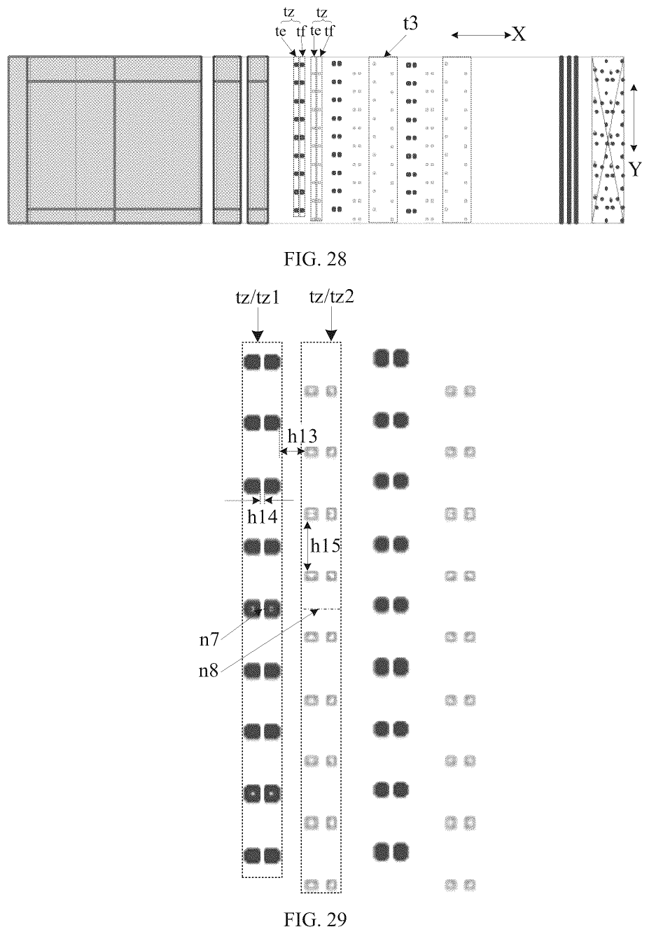

In a fifth case, referring to FIG. 28 and FIG. 29, the plurality of projection columns t form a plurality of projection column groups tz. Each of the plurality of projection column groups tz includes a fifth projection column te and a sixth projection column tf that are adjacent. The fifth projection column te and the sixth projection column tf in one of two adjacent projection column groups tz each include the multiple first projections t1 arranged in the second direction Y, and the fifth projection column te and the sixth projection column tf in the other of two adjacent projection column groups tz each include the multiple second projections t2 arranged in the second direction Y.

That is, projections in two projection columns t in each projection column group tz only include the multiple first projections, or only include the multiple second projections.

In some embodiments, referring to FIG. 29, a distance h13 between adjacent projection column groups tz in the first direction X is greater than a distance h14 between the fifth projection column te and the sixth projection column tf in each of the plurality of projection column groups tz in the first direction X. The distance between adjacent projection column groups tz in the first direction X may refer to a distance between two closest projection columns in the adjacent projection column groups tz in the first direction X. In two closest projection columns t, one projection column t is the sixth projection column tf in a projection column group tz, and the other projection column is the fifth projection column te in another projection column group tz.

For example, assuming that the plurality of projection columns t arranged in the first direction X are the fifth projection column te and the sixth projection column tf in the first projection column group tz1, and the fifth projection column te and the sixth projection column tf in the second projection column group tz2 in sequence, then a distance between the first projection column group tz1 and the second projection column group tz2 in the first direction X may refer to a distance between the sixth projection column tf in the first projection column group tz1 and the fifth projection column te in the second projection column group tz2 in the first direction X.

Illustratively, the distance h13 between adjacent projection column groups tz in the first direction X ranges from 16 μm to 36 μm, and the distance h14 between the fifth projection column te and the sixth projection column tf in each of the plurality of projection column groups tz in the first direction X ranges from 2 μm to 6.5 μm.

In some embodiments, the distance between two adjacent projections arranged in the second direction Y in each projection column t in the second direction Y is the same. For example, the distance h15 between two adjacent projections arranged in the second direction Y in each projection column t in the second direction Y ranges from 2 μm to 30 μm.

In addition, two adjacent projection column groups tz are staggered in the second direction Y. For example, for two adjacent projection column groups tz, a center line n7 of projections in one projection column group tz in the first direction X and a center line n8 of two adjacent projections arranged in the second direction Y in the other projection column group tz in the first direction X are approximately in the same horizontal line.

In the embodiments of the present disclosure, it can be seen referring to FIG. 20, FIG. 22, FIG. 24, FIG. 26, and FIG. 28 that a plurality of third vias are defined in the first insulation layer 106, and an orthographic projection of each of the plurality of third vias on the base substrate 101 form a third projection t3. The plurality of third vias are designed to connect the first trace layer a1 to the auxiliary connection structure 103. That is, a number of vias in the first insulation layer 106 is greater than a number of vias in the third insulation layer 109, such that the uniformity of the vias is ensured on the premise of the reliability of connection between the first layer trace a1 and the auxiliary connection structure 103.

In the embodiments of the present disclosure, the display panel 10 further includes a first source and drain layer (SD1), a first planarization layer (PLN1), a second source and drain layer (SD2), a second planarization layer (PLN2), a third source and drain layer (SD3), a third planarization layer (PLN3), and an anode layer that are stacked in a direction away from the base substrate 101 in sequence.

For the above first implementation, referring to FIG. 2, the power trace 105 transmits the power signal to the auxiliary connection structure 103 over a single trace layer (the first trace layer a1). The first trace layer a1 is disposed in the third source and drain layer (SD3), the auxiliary connection structure 103 is disposed in the anode layer, and the first insulation layer 106 is the third planarization layer (PLN3). That is, the first trace layer a1 is connected to the auxiliary connection structure 103 through the first connection region 106a in the third planarization layer (PLN3).

In general, as the first source and drain layer (SD1) and the second source and drain layer (SD2) include other circuit patterns k in the GOA circuit, or include other signal traces, the circuit patterns k in the GOA circuit (or other signal traces) may be affected in the case that the signal is transmitted over the trace in the first source and drain layer (SD1) or the second source and drain layer (SD2) in the power trace 105. Thus, in the case that the signal is transmitted over the trace in the first source and drain layer (SD1) or the second source and drain layer (SD2) in the power trace 105, the power trace 105 and the circuit patterns k in the GOA circuit (or other signal traces) are staggered in the first direction X. In this case, the frame of the display panel 10 is wide, which is not conductive to the narrow frame.

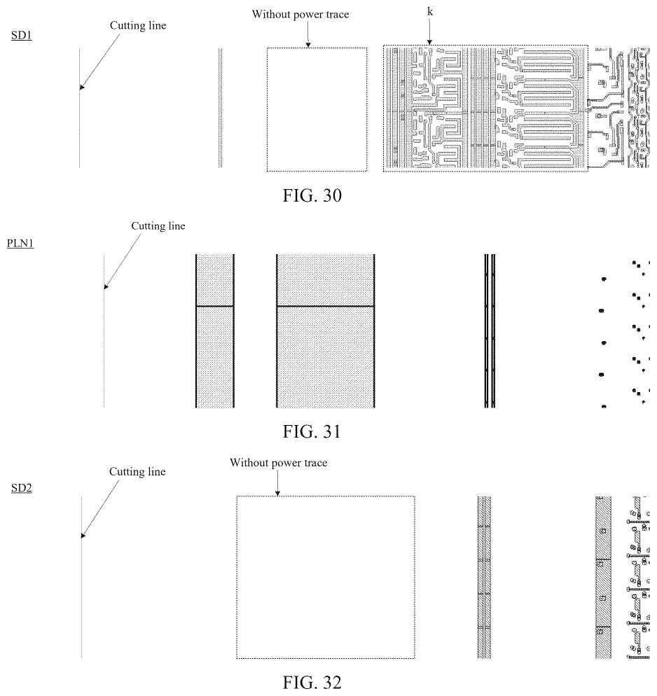

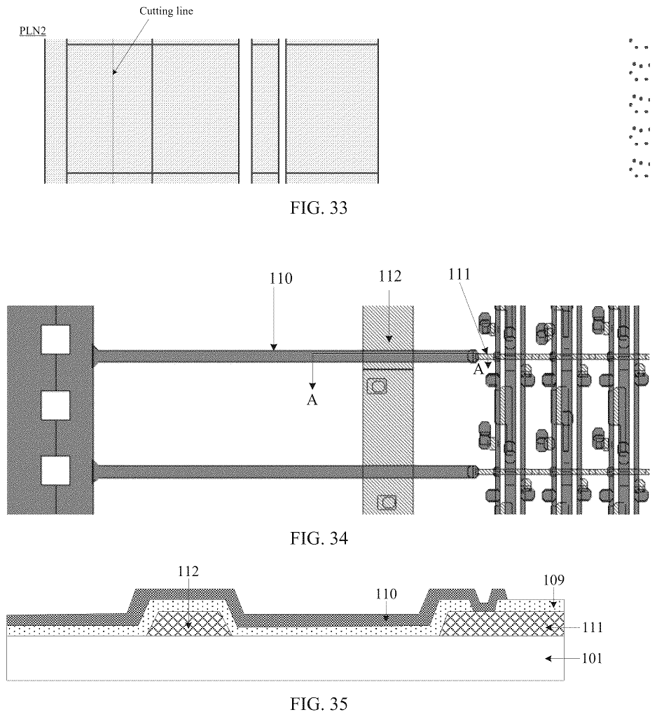

Thus, in the first implementation in the present disclosure, referring to FIG. 30 to FIG. 33, the power trace is not disposed in the first source and drain layer (SD1) or the second source and drain layer (SD2). In addition, referring to FIG. 6, the first trace layer a1 in the power trace 105 is disposed in the third source and drain layer (SD3). Thus, the mutual effect of the first trace layer a1 and the circuit patterns k in the GOA circuit (or other signal traces) is avoided. That is, an overlapping region is present between the orthographic projection of the first trace layer a1 on the base substrate 101 and an orthographic projection of the circuit pattern k in the GOA circuit (or another signal trace) on the base substrate 101, such that a size of the frame of the display panel 10 is reduced, and the narrow frame is achieved.

For the above second implementation, the power trace 105 transmits the power signal to the auxiliary connection structure 103 over three trace layers (the second trace layer a2, the third trace layer a3, and the first trace layer a in sequence). The second trace layer a2 is disposed in the first source and drain layer (SD1), the third trace layer a3 is disposed in the second source and drain layer (SD2), the first trace layer a1 is disposed in the third source and drain layer (SD3), and the auxiliary connection structure 103 is disposed in the anode layer. The second insulation layer 108 is the first planarization layer (PLN1), the third insulation layer 109 is the second planarization layer (PLN2), and the first insulation layer 106 is the third planarization layer (PLN3).

The second trace layer a2 is connected to the third trace layer a3 through the second connection region 108a in the first planarization layer (PLN1), the third trace layer a3 is connected to the first trace layer a1 through the third connection region 109a in the second planarization layer (PLN2), and the first trace layer a1 is connected to the auxiliary connection structure 103 through the first connection region 106a in the third planarization layer (PLN3).

The second side face a2a close to the plurality of pixel units 102 in the second trace layer a2 is farther away from the plurality of plurality of pixel units 102 than the third side face a3a close to the plurality of pixel units 102 in the third trace layer a3 and the first side face a1a close to the plurality of pixel units 102 in the first trace layer a1. That is, the power trace 105 introduces the power signal over the first trace layer a1, the second trace layer a2, and the third trace layer a3, and transmits the power signal to the auxiliary connection structure 103 over the third trace layer a3 and the first trace layer a1.

It should be noted that the third trace layer a3 in the power trace 105 is disposed in the second source and drain layer (SD2), and a clock signal line in the GOA circuit includes a portion in the second source and drain layer (SD2). Thus, referring to FIG. 12, for avoidance of the effect of the third trace layer a3 and the clock signal line on the layout of the second source and drain layer (SD2), the third trace layer a3 includes a first trace pattern a31 and a second trace pattern a32 that each have a gap, and the clock signal line includes gaps in the first trace pattern a31 and the second trace pattern a32.

One part of the plurality of first vias in the third connection region 109a in the second planarization layer (PLN2) is designed to connect the first trace pattern a31 and the first trace layer a1, and the other part of the plurality of first vias in the third connection region 109a in the second planarization layer (PLN2) is designed to connect the second trace pattern a32 and the first trace layer a1.

In the embodiments of the present disclosure, the power trace 105 is connected to the auxiliary connection structure 104 through the auxiliary connection structure 103 to supply a negative power signal (the VSS signal) to the cathode layer. That is, the power trace 105 is a negative power trace (the VSS trace).

Referring to FIG. 1, the power trace 105 at least includes a first portion 1051 and a second portion 1052. The first portion 1051 is disposed on a side, away from the plurality of pixel units 102, of the blocking structure 107 and is configured to receive the VSS signal. For example, the first portion 1051 is connected to a drive chip, and is configured to receive a VSS power signal supplied by the drive chip. The second portion is connected to the auxiliary connection structure 104 through the auxiliary connection structure 103.

In some embodiments of the present disclosure, the power trace 105 at least includes two first portions 1051. The two first portions 1051 are disposed approximately symmetrical along the longitudinal axis m of the base substrate 101 (the longitudinal axis M extends in the second direction Y) at an edge on a side, away from the plurality of pixel units 102, of the blocking structure 107.

In some embodiments, portions of the two first portions 1051 in the power trace 105 close to the trace-entering opening are disposed on two sides of the base substrate 101, for example, close to two side edges parallel to the longitudinal axis M.

Referring to FIG. 3, the peripheral region 101b of the base substrate 101 includes a first region 101b1 and a second region 101b2 that are disposed on two sides of the display region 101a and are opposite to each other, and a third region 101b3 and a fourth region 101b4 that are disposed on two sides of the display region 101a and are opposite to each other. The first region 101b1 and the second region 101b2 are stripe regions extending in the first direction X, and the third region 101b3 and the fourth region 101b4 are stripe regions extending in the second direction Y. For example, the first region 101b1 is a region in the peripheral region on an upper side of the display region 101a, the second region 101b2 is a region in the peripheral region on a lower side of the display region 101a, the third region 101b3 is a region in the peripheral region on a left side of the display region 101a, and the fourth region 101b4 is a region in the peripheral region on a right side of the display region 101a.

In the embodiments of the present disclosure, the first region 101b1 is in direct contact with the second region 101b2. For example, the first region 101b1 and the second region 101b2 are an integrated structure. In some embodiments, referring to FIG. 1, the trace-entering opening of the power trace 105 is in the fourth region 101b4. That is, two first portions 1051 of the power trace 105 are disposed in the fourth region 101b4 and are connected to the second portion 1052 running through the blocking structure 107 from the fourth region 101b4. The second portion 1052 is a non-enclosed structure, and includes a first trace portion 10521, a second trace portion 10522, and a third trace portion 10523 that are connected to each other in sequence. The first trace portion 10521 is disposed in the third region 101b3, the second trace portion 10522 is disposed in the first region 101b1, and the third trace portion 10523 is disposed in the fourth region 101b4.

In above embodiments, the power trace 105 is disposed in the peripheral region 101b, and thus the connection position of the power trace 105 and the auxiliary connection structure 103 is also in the peripheral region 101b. But distances between the plurality of pixel units 102 in the display region 101a and the peripheral region 101b are different, and thus a voltage drop is present in power signals of the cathode layers 104 corresponding to pixel units 102 in different regions in the display region 101a in the case that the power trace 105 in the peripheral region 101b transmits the power signal to the cathode layer 104 through the auxiliary connection structure 103.

Thus, for reduction of the drop of the power signal, referring to FIG. 34, the display panel 10 further includes a plurality of first transmission lines 110, a plurality of second transmission lines 111, and a plurality of third transmission lines (not shown in the drawing) that are disposed in the display region.

The plurality of first transmission lines 110, the plurality of second transmission lines 111, and the plurality of third transmission lines are connected in one-to-one correspondence. That is, for the corresponding first transmission line 110, the second transmission line 111, and the third transmission line, one end of the first transmission line 110 is connected to the first trace portion 10521 of the power trace 105, the other end of the first transmission line 110 is connected to one end of the second transmission line 111, the other end of the second transmission line 111 is connected to one end of the third transmission line, and the other end of the third transmission line is connected to the third trace portion 10523 of the power trace 105.

The connection between the first trace portion 10521 and the first transmission line 110 refers to connection between the first trace layer a1, in the third source and drain layer (SD3), of the first trace portion 10521 and the first transmission line 110. The connection between the third trace portion 10523 and the third transmission line refers to connection between the first trace layer a1, in the third source and drain layer, of the third trace portion 10523 and the first transmission line 110.

In some embodiments, the first transmission line 110 is disposed in the third region 101b3, the second transmission line 111 is disposed in the first region 101b1, and the third transmission line is disposed in the fourth region 101b4. The second transmission line 111 is connected to a portion of the cathode layer 104 in the display region 101a. That is, the power trace 105 transmits the power signal to the cathode layer 104 in the display region 101a over the transmission line to reduce the voltage drop in power signals of the cathode layers 104 corresponding to the pixel units 102 in different regions in display region 101a.

In some embodiments, the plurality of first transmission lines 110 and the plurality of third transmission lines are disposed in the third source and drain layer (SD3), and the plurality of second transmission lines 111 are disposed in the second source and drain layer (SD2). As the plurality of first transmission lines 110 and the first trace layer a1 in the first trace portion 10521 are disposed in the same layer, portions of the plurality of first transmission lines 110 and the first trace layer a1 in the first trace portion 10521 in the third region 101b3 are an integrated structure. As the plurality of third transmission lines and the first trace layer a1 in the third trace portion 10523 are disposed in the same layer, portions of the plurality of third transmission lines and the first trace layer a1 in the third trace portion 10523 in the fourth region 101b4 are an integrated structure. Using the connection between the first transmission line 110 and the second transmission line 111 as an example, referring to FIG. 35, the first transmission line 110 is connected to the second transmission line 111 through the via in the third insulation layer (the second planarization layer PLN2).

Referring to FIG. 35, the display panel 10 further includes a reset power line 112 that are disposed between the first trace layer a1 in the power trace 105 and the display region 101a and disposed in the second source and drain layer (SD2). In addition, an orthographic projection of the reset power line 112 on the base substrate 101 is partially overlapped with an orthographic projection of the first transmission line 110 (or the third transmission line) on the base substrate 101. Thus, the reset power line 112 and the second transmission line 111 in the same layer do not affect the layouts thereof.

It can be seen referring to FIG. 2 that the display panel 10 further includes an encapsulation film layer 113. The encapsulation film layer 113 is disposed on a side, away from the base substrate 101, of the cathode layer of the pixel unit 102, and covers a region enclosed by the blocking structure 107. Referring to FIG. 2, a boundary of the region covered by the encapsulation film layer 113 is disposed on a side, away from the plurality of pixel units 102, of the blocking structure 107.

Referring to FIG. 1 and FIG. 2, the blocking structure 107 includes a first blocking dam 1071 and a second blocking dam 1072. The first blocking dam 1071 is closer to the display region 101a than the second blocking dam 1072.

In some embodiments, a height of the first blocking dam 1071 is less than a height of the second blocking dam 1072. Illustratively, in the blocking structure 107 shown in FIG. 2, the first blocking dam 1071 includes patterns in the first planarization layer PLN1, patterns in the second planarization layer PLN2, patterns in a pixel define layer, and patterns in a support layer. The second blocking dam 1072 includes patterns in the first planarization layer PLN1, patterns in the second planarization layer PLN2, patterns in the third planarization layer PLN3, patterns in the pixel define layer, and patterns in the support layer. Thus, a layer of the patterns in the third planarization layer PLN3 is added in the second blocking dam 1072 relative to the first blocking dam 1071. The pixel define layer and the support layer are not shown in above accompanying drawings. The pixel define layer is disposed on the side, away from the base substrate, of the cathode layer, and the support layer r is disposed on the side, away from the base substrate, of the pixel define layer. The method is applicable to the first implementation.

In some embodiments, a height of the first blocking dam 1071 is equal to a height of the second blocking dam 1072. The first blocking dam 1071 and the second blocking dam 1072 each include patterns in the second planarization layer PLN2, patterns in the third planarization layer PLN3, patterns in a pixel define layer, and patterns in a support layer. The method is applicable to the second implementation.

In the embodiments of the present disclosure, the encapsulation film layer 113 further includes a first film layer 1131, a second film layer 1132, and a third film layer 1133 that are staked in the direction away from the base substrate 101.

In some embodiments, the first film layer 1131 and the third film layer 1133 are made of an inorganic material, a second film layer 1132 is made of an organic material. For example, the first film layer 1131 and the third film layer 1133 are made of one or more inorganic oxides, for example, silicon nitride (SiNx), silicon oxide (SiOx), and silicon oxide nitrogen (SiOxNy). The second film layer 1132 is made of a resin material. The resin is a thermoplastic resin or a thermosetting resin. The thermoplastic resin may include an acrylic (PMMA) resin, and the thermosetting resin may include an epoxy resin.

It should be noted that the second film layer 1132 is disposed in the region enclosed by the blocking structure 107, and the first film layer 1131 and the third film layer 1133 cover the region enclosed by the blocking structure 107 and cover the blocking structure 107. That is, an orthographic projection of the blocking structure 107 on the base substrate 101 is within an orthographic projection of the encapsulation film layer 113 on the base substrate 101, such that the encapsulation film layer 113 efficiently encapsulates various structures in the region enclosed by the blocking structure 107.

In some embodiments, the second film layer 1132 is manufactured by an ink jet printing (IJP) process, and the first film layer 1131 and the third film layer 1133 are manufactured by a chemical vapor deposition (CVD) process.

In the embodiments of the present disclosure, the display panel includes a plurality of sets of first GOA circuits in the third region and a plurality of sets of second GOA circuits in the fourth region. Each set of GOA circuits in the plurality of sets of first GOA circuits and the plurality of sets of second GOA circuits includes a plurality of GOA circuit units arranged in the second direction Y. The plurality of sets of first GOA circuits are arranged in the first direction X, and the plurality of sets of second GOA circuits are arranged in the first direction X.

In some embodiments, the display panel includes two sets of first GOA circuits and two sets of second GOA circuits. Alternatively, the display panel includes three sets of first GOA circuits and three sets of second GOA circuits. Compared with the solution of three sets of GOA circuits, the size of the frame of the display panel is less in the solution of two sets of GOA circuits, and the narrow frame is achieved.

In general, a circuit of a low temperature poly-silicon (LTPS) display panel is complex, and thus the display panel needs to GOA circuits supplying three types of signals. In this case, two sides of the display panel each include two sets of GOA circuits in the case that the size of the frame of the display panel needs to be reduced. In addition, one first GOA circuit and one second GOA circuit transmit a first type of signals, and the other first GOA circuit transmits a second type of signals, and the other second GOA circuit transmit a third type of signals transmits a first type of signals. The solution is referred as a two-sided driving of a type of signals and single-sided driving of another two types of signals.

In some embodiments, in the first implementation (the power trace 105 transmits the power signal to the auxiliary connection structure 103 over a single trace layer), the first trace layer a1 in the third source and drain layer SD3 covers an outmost GOA circuit, and a width of the first trace layer a1 is 245 μm. In addition, in the case that the first trace layer a1 runs through the GOA circuit (the SD1 layer) and the reset power line (the SD2 layer), the first trace layer a1 is connected to the second transmission line 111 in the display region without changing the trace, such that the VSS signal is transmitted. In the solution, the size of the frame is reduced from 920 μm to 770 μm, such that the narrow frame is achieved.

In summary, the embodiments of the present disclosure provide a display panel. The display panel includes the power trace and the auxiliary connection structure, and the first connection region is disposed in the first insulation layer between the first trace layer in the power trace and the auxiliary connection structure. As the ratio of the area of the orthographic projection of the first connection region on the base substrate to the area of the overlapping region between the orthographic projection of the power trace on the base substrate and the orthographic projection of the auxiliary connection structure on the base substrate is great, the contacting area of the first trace layer in the power trace and the auxiliary connection structure is great, the reliability of the connection between the first trace layer in the power trace and the auxiliary connection structure is improved, and the reliability of transmission of the power signal from the power trace to the auxiliary connection structure is further improved, such that the pixel unit emits light normally, and the display effect of the display panel is great.

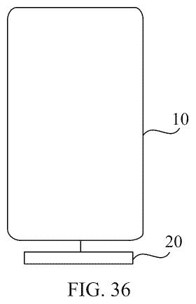

FIG. 36 is a schematic structural diagram of a display device according to some embodiments of the present disclosure. As shown in FIG. 36, the display device includes a power supply assembly 20 and the display panel 10 in the above embodiments. The power supply assembly 20 is configured to supply power to the display panel 10.

In some embodiments, the display device is a liquid crystal display (LCD) display device, an LTPS display device, an organic light-emitting diode (OLED) display device, a quantum dot light emitting diodes display device. The display device is any suitable display device, including but not limited to a mobile phone, a tablet, a television, a monitor, a laptop computer, a digital photo frame, a navigators, an e-books, and any other products or assemblies with the display function.

In addition, the display device is applicable to a fanout in AA (FIP) technology or a VSS in AA (SIP) technology.

The display device has basically the same technical effects as the touch electrode structure in above embodiments, and thus the technical effects of the display device are not repeated herein for conciseness.

The terms used in the embodiments of the present disclosure are only used to explain the embodiments of the present disclosure, and are not intended to limit the present disclosure. Unless otherwise defined, technical or scientific terms used in the present disclosure shall have ordinary meaning understood by persons of ordinary skill in the art to which the disclosure belongs.

The terms “first,” “second,” “third,” and the like in the description and claims of the present disclosure are not intended to indicate or imply any sequence, number or importance, and are only used to distinguish different portions. Similarly, the terms “a,” “an,” and the like are not intended to limit the quantity, and only represent that at least one exists. The terms “include” or “include” and the like are used to indicate that the element or object preceding the terms covers the element or object following the terms and its equivalents, and shall not be understood as excluding other elements or objects. The terms “connection,” “contact,” and the like are not intended to be limited to physical or mechanical connections, but may include electrical connections, either direct or indirect connection. The terms “on,” “under,” “left,” and “right” are only used to indicate the relative positional relationship. When the absolute position of the described object changes, the relative positional relationship may change accordingly. The terms “connection” and “coupling” refer to electrical connection.

Described above are merely optional embodiments of the present disclosure, and are not intended to limit the present disclosure. Any modifications, equivalent replacements, improvements and the like made within the spirit and principles of the present disclosure should be encompassed within the scope of protection of the present disclosure.

1. A display panel, comprising:
a base substrate, having a display region and a peripheral region surrounding the display region;
a plurality of pixel units, disposed in the display region;
an auxiliary connection structure, wherein the auxiliary connection structure and anode layers of the plurality of pixel units are disposed in a same layer in the peripheral region;
a cathode layer, disposed on a side, away from the base substrate, of the auxiliary connection structure, wherein the cathode layer is connected to the auxiliary connection structure; and
at least one power trace, configured to receive a first power signal, wherein the at least one power trace is connected to the auxiliary connection structure;
wherein the at least one power trace at least comprises a first trace layer, wherein a first insulation layer is disposed between the first trace layer and the auxiliary connection structure, the first insulation layer having a first connection region, wherein the first trace layer and the auxiliary connection structure are connected to each other in the first connection region, and a ratio of an area of an orthographic projection of the first connection region on the base substrate to an area of an overlapping region between an orthographic projection of the at least one power trace on the base substrate and an orthographic projection of the auxiliary connection structure on the base substrate is greater than a ratio threshold.

2. The display panel according to claim 1, wherein at least a plurality of slots arranged in a first direction and extending in a second direction are defined in the first connection region, wherein the second direction is intersected with the first direction, and the first trace layer is connected to the auxiliary connection structure via the plurality of slots.

3. The display panel according to claim 2, wherein a plurality of communication slots between any two adjacent slots of the plurality of slots are further defined in the first connection region, and arranged in the second direction and extend in the first direction.

4. The display panel according to claim 3, wherein a plurality of first vent holes are defined in the auxiliary connection structure, and the plurality of slots and the plurality of communication slots between any two adjacent slots of the plurality of slots form a plurality of block patterns, wherein an orthographic projection of each of the plurality of block patterns on the base substrate covers an orthographic projection of one of the plurality of first vent holes on the base substrate.

5. The display panel according to claim 4, wherein a shape of the orthographic projection of each of the plurality of block patterns on the base substrate is the same as a shape of the orthographic projection of the one of the plurality of first vent holes on the base substrate, and a center of the orthographic projection of each of the plurality of block patterns on the base substrate is coincided with a center of the orthographic projection of the one of the plurality of first vent holes on the base substrate.

6. The display panel according to claim 5, wherein the shape of the orthographic projection of each of the plurality of block patterns on the base substrate and the shape of the orthographic projection of the one of the plurality of first vent holes on the base substrate are both rectangles, and a distance between any boundary of one of the plurality of block patterns and a boundary, at a minimum distance from the one of the plurality of block patterns, in four boundaries of the one of the plurality of first vent holes ranges from 5 microns to 9 microns.

7. The display panel according to claim 4, wherein a plurality of second vent holes are defined in the first trace layer, wherein a center of an orthographic projection of each of the plurality of second vent holes on the base substrate is coincided with a center of the orthographic projection of each of the plurality of block patterns on the base substrate, an area of the orthographic projection of each of the plurality of second vent holes on the base substrate is less than an area of the orthographic projection of each of the plurality of block patterns on the base substrate and is greater than or equal to an area of the orthographic projection of the one of the plurality of first vent holes on the base substrate.

8. The display panel according to claim 1, wherein the at least one power trace comprises a second trace layer, a third trace layer, and the first trace layer that are stacked in a direction away from the base substrate; and the display panel further comprises a second insulation layer between the second trace layer and the third trace layer, and a third insulation layer between the third trace layer and the first trace layer;
wherein the second insulation layer has a second connection region, and the third insulation layer has a third connection region, wherein the first trace layer and the second trace layer are connected to each other in the second connection region, and the second trace layer and the third trace layer are connected to each other in the third trace layer.

9. The display panel according to claim 8, wherein the first trace layer has a first side face close to the plurality of pixel units, the second trace layer has a second side face close to the plurality of pixel units, and the third trace layer has a third side close to the plurality of pixel units, wherein the third side face and the first side face are closer to the plurality of pixel units than the second side face.

10. The display panel according to claim 9, wherein
an opening is defined in the second connection region is, wherein the opening is designed to expose all regions in the second trace layer;
a plurality of first vias are defined in the third connection region, wherein each of the plurality of first vias is designed to expose part of the third trace layer; and
a plurality of second vias are defined in the first connection region, wherein each of the plurality of second vias is designed to expose part of the first trace layer;
wherein orthographic projections of the plurality of first vias on the base substrate are not overlapped with orthographic projections of the plurality of second vias on the base substrate.

11. The display panel according to claim 10, wherein the plurality of first vias form a plurality of first projections, and the plurality of second vias form a plurality of second projections, wherein the plurality of first projections and the plurality of second projections form a plurality of projection columns arranged in a first direction and extending in a second direction, each of the plurality of projection columns comprising multiple first projections, multiple second projections, or a combination thereof; and each of the plurality of first projections is an orthographic projection of one of the plurality of first vias on the base substrate, and each of the plurality of second projections is an orthographic projection of one of the plurality of second vias on the base substrate.

12. The display panel according to claim 11, wherein each of the plurality of projection columns comprises the multiple first projections and the multiple second projections that are staggered; wherein one projection in any two adjacent projections arranged in the first direction is a first projection in a first projection column in any two adjacent projection columns, and another projection in the any two adjacent projections arranged in the first direction is a second projection in a second projection column in the any two adjacent projection columns.

13. The display panel according to claim 11, wherein each of the plurality of projection columns comprises the multiple first projections and the multiple second projections that are staggered, wherein the multiple first projections and the multiple second projections in each of the plurality of projection columns are in one-to-one correspondence with each other, and the multiple first projections and corresponding second projections form a plurality of projection groups, wherein a distance between adjacent projection groups in the second direction is greater than a distance between the first projection and the second projection in each of the plurality of projection groups in the second direction.

14. The display panel according to claim 11, wherein
one of two adjacent projection columns comprises the multiple first projections, and another of the two adjacent projection columns comprises the multiple second projections; and
each of the plurality of projection columns comprises a plurality of projection groups, wherein each of the plurality of projection groups comprises two projections adjacent in the second direction in the each of the plurality of projection columns, and a distance between adjacent projection groups in the second direction is greater than a distance between the two projections in each of the plurality of projection groups in the second direction.

15. The display panel according to claim 12, wherein the two adjacent projection columns are staggered in the second direction.

16. The display panel according to claim 11, wherein the plurality of projection columns form a plurality of projection column groups, wherein each of the plurality of projection column groups comprises a third projection column and a fourth projection column that are adjacent;
wherein the third projection column comprises the multiple first projections arranged in the second direction, and the fourth projection column comprises the multiple second projections arranged in the second direction and corresponding to the multiple first projections in the third projection column, wherein each of the multiple second projections and a corresponding first projection are arranged in the first direction, and a distance between any adjacent projection column groups in the first direction is greater than a distance between the third projection column and the fourth projection column in each of the plurality of projection column groups in the first direction.

17. The display panel according to claim 11, wherein the plurality of projection columns form a plurality of projection column groups, wherein each of the plurality of projection column groups comprises a fifth projection column and a sixth projection column that are adjacent;
wherein the fifth projection column and the sixth projection column in one of any two adjacent projection column groups each comprise the multiple first projections arranged in the second direction, and the fifth projection column and the sixth projection column in another of the any two adjacent projection column groups each comprise the multiple second projections arranged in the second direction, wherein a distance between adjacent projection column groups in the first direction is greater than a distance between the fifth projection column and the sixth projection column in each of the plurality of projection column groups in the first direction.

18. The display panel according to claim 16, wherein two adjacent projection column groups are staggered in the second direction.

19. The display panel according to claim 2, comprising: a first source and drain layer, a first planarization layer, a second source and drain layer, a second planarization layer, a third source and drain layer, a third planarization layer, and an anode layer that are stacked in a direction away from the base substrate in sequence;
wherein the first trace layer in the at least one power trace is disposed in the third source and drain layer, a second trace layer in the at least one power trace is disposed in the first source and drain layer, and a third trace layer in the at least one power trace is disposed in the second source and drain layer; and the first insulation layer is the third planarization layer, a second insulation layer is the first planarization layer, and a third insulation layer is the second planarization layer.

20. A display device, comprising: a power supply assembly and a display panel; wherein
the display panel includes:
a base substrate, having a display region and a peripheral region surrounding the display region;
a plurality of pixel units, disposed in the display region;
an auxiliary connection structure, wherein the auxiliary connection structure and anode layers of the plurality of pixel units are disposed in a same layer in the peripheral region;
a cathode layer, disposed on a side, away from the base substrate, of the auxiliary connection structure, wherein the cathode layer is connected to the auxiliary connection structure; and
at least one power trace, configured to receive a first power signal, wherein the at least one power trace is connected to the auxiliary connection structure;
wherein the at least one power trace at least comprises a first trace layer, wherein a first insulation layer is disposed between the first trace layer and the auxiliary connection structure, the first insulation layer having a first connection region, wherein the first trace layer and the auxiliary connection structure are connected to each other in the first connection region, and a ratio of an area of an orthographic projection of the first connection region on the base substrate to an area of an overlapping region between an orthographic projection of the at least one power trace on the base substrate and an orthographic projection of the auxiliary connection structure on the base substrate is greater than a ratio threshold; and
the power supply assembly is configured to supply power to the display panel.
